(19) United States
(12) Patent Application Publication
(10) Pub. No.: US 2025/0311320 A1
(43) Pub. Date: Oct. 2, 2025

(54) EPI REGION WITH TRENCH EXTENSION AND WRAPAROUND CONTACT

(71) Applicant: INTERNATIONAL BUSINESS MACHINES CORPORATION, Armonk, NY (US)

(72) Inventors: Debarghya Sarkar, Latham, NY (US); Ruilong Xie, Niskayuna, NY (US); Chen Zhang, Santa Clara, CA (US); Shogo Mochizuki, Mechanicville, NY (US); Tao Li, Slingerlands, NY (US)

(21) Appl. No.: 18/618,530

(22) Filed: Mar. 27, 2024

(51) Int. Cl. H01L 29/06; H01L 23/528; H01L 27/088; H01L 29/417; H01L 29/423; H01L 29/66; H01L 29/775; H01L 29/786

(52) U.S. Cl. CPC H10D 62/115; H01L 23/528; H10D 30/014; H10D 30/43; H10D 30/6735; H10D 30/6757; H10D 62/121; H10D 64/017; H10D 64/254; H10D 84/83

(57) ABSTRACT

A semiconductor device includes a shallow trench isolation region having a depth. An asymmetric electrode has an epitaxial region outside the depth of the shallow trench isolation region; and an epitaxial extension portion within the depth of the shallow trench isolation region and connected to the epitaxial region. A backside contact is in contact with the epitaxial extension portion to provide a wraparound contact to reduce contact resistance.

### BACKGROUND

The present invention generally relates to semiconductor devices and processing methods, and more particularly to field effect transistors (FETs) with an asymmetric epitaxially grown region with a buried trench extension that interfaces with a wraparound backside contact.

With backside processing of field effect transistors, poor backside overlay and critical dimension control for backside contacts leads to opens and shorts. Misaligned backside contacts may not result in the removal of all dielectric material or may not land on an intended conductive target, leading to opens. Backside contacts with large critical dimensions could connect adjacent conductive structures, leading to shorts between the conductive structures.

To achieve performance benefits for backside contacts, a low contact resistance is needed between the backside contact and a source/drain region to which it connects. However, effective contact resistance improvements are difficult to achieve, especially with reductions in scaling of constant poly pitch (CPP). Controlling backside contact resistance (Rc) is challenging due to backside thermal budget limitations and insufficient space to permit adequate electrical contact.

### SUMMARY

In accordance with an embodiment of the present invention, a semiconductor device includes a shallow trench isolation region having a depth. An asymmetric electrode has an epitaxial region outside the depth of the shallow trench isolation region; and an epitaxial extension portion within the depth of the shallow trench isolation region and connected to the epitaxial region. A backside contact is in contact with the epitaxial extension portion to provide a wraparound contact to reduce contact resistance.

In other embodiments, the asymmetric electrode can include a source region or a drain region of a field effect transistor and another of the source region or the drain region is contacted by a contact from a topside of the semiconductor device. The asymmetric electrode can include an overburden disposed between the epitaxial region and the epitaxial extension portion. The backside contact can be disposed within the depth of the shallow trench isolation region. The epitaxial region can include a width that is greater than a width of the epitaxial extension portion. The epitaxial extension portion can include a faceted surface that includes horizontally and vertically disposed facets and the backside contact interfaces with the horizontally and the vertically disposed facets. The epitaxial region can be on a frontside of the semiconductor device, and the epitaxial extension portion can be on a backside of the semiconductor device. The backside contact can include a width that spans between adjacent gate structures on the backside of the semiconductor device.

In accordance with other embodiments of the present invention, a semiconductor device includes a field effect transistor having a first electrode and a second electrode. The first electrode including an asymmetric electrode has an epitaxial region on a frontside of the semiconductor device and an epitaxial extension portion on a backside of the semiconductor device connected to the epitaxial region. The epitaxial extension portion includes a faceted surface. A backside contact in contact with the faceted surface from the backside provides a wraparound contact to reduce contact resistance, and a frontside is in contact with the second electrode from the frontside.

In other embodiments, the asymmetric electrode can include a source region or a drain region of a field effect transistor and another of the source region or the drain region is contacted by a contact from a topside of the semiconductor device. The asymmetric electrode can include an overburden disposed between the epitaxial region and the epitaxial extension portion. The backside contact can be disposed within the depth of the shallow trench isolation region. The epitaxial region can include a width that is greater than a width of the epitaxial extension portion. The epitaxial extension portion can include a faceted surface that includes horizontally and vertically disposed facets and the backside contact interfaces with the horizontally and the vertically disposed facets. The epitaxial region can be on a frontside of the semiconductor device, and the epitaxial extension portion can be on a backside of the semiconductor device. The backside contact can include a width that spans between adjacent gate structures on the backside of the semiconductor device.

In accordance with other embodiments of the present invention, a semiconductor device includes a field effect transistor having a first electrode and a second electrode. The first electrode and the second electrode each include an epitaxial region on a frontside of the semiconductor device. The first electrode has an epitaxial extension portion on a backside of the semiconductor device and is connected to the epitaxial region of the first electrode. The epitaxial extension portion includes a faceted surface that extends toward the backside of the semiconductor device. The faceted surface includes horizontally and vertically disposed facets. A backside contact in contact with the faceted surface from the backside provides a wraparound contact that interfaces with the horizontally and the vertically disposed facets to reduce contact resistance, and a frontside contact is in contact with the epitaxial region of the second electrode from the frontside.

In other embodiments, the asymmetric electrode can include an overburden disposed between the epitaxial region and the epitaxial extension portion. The backside contact can be disposed within the depth of the shallow trench isolation region. The epitaxial region can include a width that is greater than a width of the epitaxial extension portion. The epitaxial region can be on a frontside of the semiconductor device, and the epitaxial extension portion can be on a backside of the semiconductor device. The backside contact can include a width that spans between adjacent gate structures on the backside of the semiconductor device.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views, taken at section lines X and Y as shown in an inset (and referred to as section X and section Y respectively), of a semiconductor device formed by processing one or more nanosheets and including epitaxial regions formed as electrodes, in accordance with an embodiment of the present invention;

FIG. 2 shows cross-sectional views, taken at section lines X and Y, of a hard mask stack being patterned over gates, in accordance with an embodiment of the present invention;

FIG. 3 shows cross-sectional views, taken at section lines X and Y, of the hard mask stack after being patterned, in accordance with an embodiment of the present invention;

FIG. 4 shows cross-sectional views, taken at section lines X and Y, of the stack of layers removed in section Y and dummy gate structures formed in section X, in accordance with an embodiment of the present invention;

FIG. 4 shows cross-sectional views, taken at section lines X and Y, after removal of a dielectric layer to expose one of the electrodes, in accordance with an embodiment of the present invention;

FIG. 5 shows cross-sectional views, taken at section lines X and Y, after removing the exposed electrodes, in accordance with an embodiment of the present invention;

FIG. 6 shows cross-sectional views, taken at section lines X and Y, after forming a protective liner, in accordance with an embodiment of the present invention;

FIG. 7 shows cross-sectional views, taken at section lines X and Y, after removing the protective liner from horizontal surfaces and further etching a trench in a depth direction as well as a lateral direction (width), in accordance with an embodiment of the present invention;

FIG. 8 shows cross-sectional views, taken at section lines X and Y, after forming a boundary surface by epitaxially growing a material within the trench, in accordance with an embodiment of the present invention;

FIG. 9 shows cross-sectional views, taken at section lines X and Y, after epitaxially growing an extension portion on the boundary surface with overburden, in accordance with an embodiment of the present invention;

FIG. 10 shows cross-sectional views, taken at section lines X and Y, after epitaxially growing an epitaxial region for an asymmetric electrode, in accordance with an embodiment of the present invention;

FIG. 11 shows cross-sectional views, taken at section lines X and Y, after frontside contacts are formed and a back end of the line layer and carrier wafer are provided, in accordance with an embodiment of the present invention;

FIG. 12 shows cross-sectional views, taken at section lines X and Y, after a substrate, etch stop layer and semiconductor layer have been removed and replaced by a dielectric layer (e.g., backside interlevel dielectric layer), in accordance with an embodiment of the present invention;

FIG. 13 shows cross-sectional views, taken at section lines X and Y, after the dielectric layer is etched to open contact holes or trenches to expose the boundary surface at selected contact positions, in accordance with an embodiment of the present invention;

FIG. 14 shows cross-sectional views, taken at section lines X and Y, after the exposed boundary surfaces are removed to expose portions of the extension portions, in accordance with an embodiment of the present invention;

FIG. 15 shows cross-sectional views, taken at section lines X and Y, after forming wraparound contacts at a backside that contact at faceted surfaces of the extension portion, in accordance with an embodiment of the present invention; and

FIG. 16 shows cross-sectional views, taken at section lines X and Y, after forming a backside interconnect layer, in accordance with an embodiment of the present invention.

### DETAILED DESCRIPTION

In accordance with embodiments of the present invention, devices and methods are described which include controlling contact resistance while increasing overlay tolerance for backside contacts. In an embodiment, a source/drain region includes an epitaxially formed region (epi region) for a field effect transistor (FET) having an extension portion. The extension portion can be grown to extend the epi region toward a backside of a semiconductor device under fabrication. The extension portion includes a shape that increases surface area. The extension portion and the epi region form part of an asymmetric electrode. When the backside contact is formed, conductive material of the backside contact wraps around the extension portion. The backside contact wraps around multiple facets of the asymmetric extension to provide a greater surface area of contact and reduce surface contact resistance (Rc).

In addition, one of the epi regions (e.g., a source region) for a FET can be connected using the backside contact while another of the epi regions (e.g., drain region) can be contacted from a frontside of the semiconductor device. It should be understood that this can be reversed, e.g., one of the epi regions (e.g., a drain region) for a FET can be connected using the backside contact while another of the epi regions (e.g., source region) can be contacted from the frontside of the semiconductor device. By alternating frontside and backside contacts, shorts of source/drain region contacts are greatly reduced or eliminated from misalignment of backside contacts.

In some embodiments, a semiconductor wafer is processed to form a semiconductor device. The semiconductor device includes a semiconductor substrate. A nanosheet is provided on the substrate and is processed to form semiconductor channels. Before source/drain regions are formed by epitaxial growth between the semiconductor channels, a trench is formed in the substrate. During epitaxial growth of the source/drain regions, an extension portion is formed for the source/drain region within the trench, which is buried in a backside region of the semiconductor device. The extension portion makes the source/drain region asymmetric as the extension portion is confined to the trench and a portion of the source/drain region that is not, extends laterally beyond the trench.

The extension portion is accessed from the backside by forming an opening in a backside dielectric layer for a backside contact. The backside contact wraps around the extension portion. The backside contact therefore has increased interfacial surface area with the extension portion, which reduces contact resistance. In an embodiment, one electrode (e.g., source or drain) associated with a device (FET) has an extension portion into the backside, whereas the other electrode is contacted at the frontside. This reduces contact density and increases overlay tolerance.

In other embodiments, a method for forming a semiconductor device includes employing a self-aligned selective recess or trench formed in a substrate at a location for an electrode. A self-aligned selective etch of a bottom dielectric isolation (BDI) is performed at the location to expose the substrate. A backside trench is formed in the substrate at the location for one electrode (e.g., source or drain). A trench sacrificial liner is formed within the trench. The trench sacrificial liner can include, e.g., SiGe. An extension portion is epitaxially grown in the trench over the trench sacrificial liner. An epi region is grown epitaxially to complete the electrode. The electrode (source or drain) can be grown monolithically with the extension portion. The trench sacrificial liner is removed. A dielectric layer is deposited, and a contact opening is formed in the dielectric layer which also exposes the extension portion. A backside wraparound contact is formed in contact with the extension portion. The extension portion includes a faceted surface that permits increased surface area for the wraparound backside contact, which in turn, reduces contact resistance Rc.

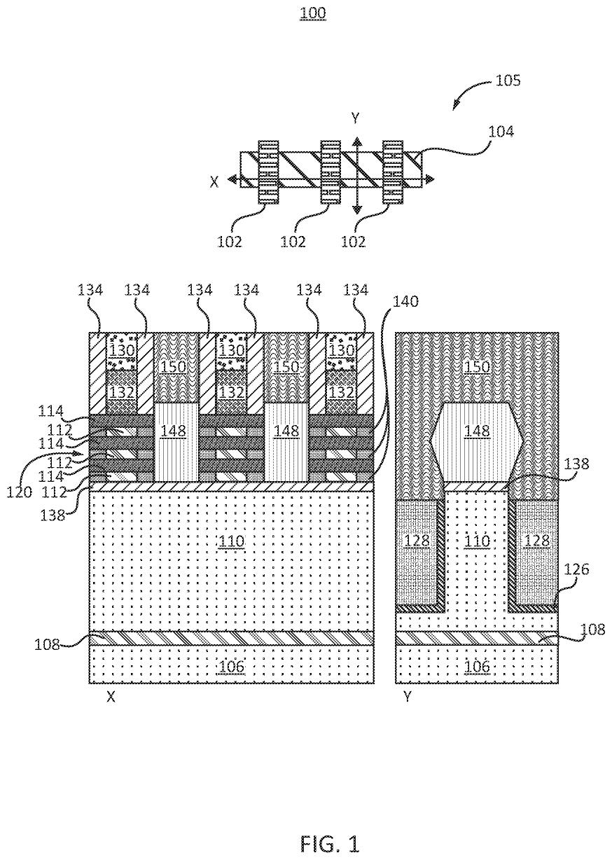

Referring now to the drawings in which like numerals represent the same or similar elements and initially to FIG. 1, devices and methods for manufacturing a nanosheet field effect transistor (FET) device are shown in accordance with embodiments of the present invention. A wafer 100 includes a substrate 106 having multiple layers on which the stacked FET device will be fabricated. FIG. 1 depicts two orthogonal views, X and Y, taken at corresponding sections X and Y in inset 105. Inset 105 shows gate lines 102 and active region lines 104 for reference. Corresponding X and Y views are depicted throughout FIGS. 1-16. Active region lines 104 represent source/drain (S/D) regions for transistor devices to be formed, and gate lines 102 are represented for such transistor devices. Transistor channels are formed on the active region lines 104 below the gate lines 102.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In one embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

A bottom dielectric isolation (BDI) 138 can be formed on the semiconductor layer 110. BDI 138 can include a nitride, such as silicon nitride, although other dielectric materials can be employed.

One or more nanosheets (NS) are applied to the semiconductor layer 110. The nanosheet includes layers of alternating semiconductor material. In an embodiment, a stack 120 includes alternating layers of a semiconductor layer 112 and a semiconductor layer 114. Each of semiconductor layers 112 and 114 are selectively removeable relative to neighboring semiconductor layers, e.g., by a selective etching process. In one embodiment, semiconductor layer 112 can include, e.g., SiGe, where Ge is between 30-55 atomic % of the compound. Semiconductor layer 114 can include, e.g., Si. It should be understood that other materials or atomic percentages can be employed for semiconductor layers 112, 114. In other embodiments, different stack orders and numbers may be employed for semiconductor layers 112, 114.

Stack 120 can be patterned to expose and etch the semiconductor layer 110. In one embodiment, a hard mask (not shown) may be formed by blanket depositing a layer of hard mask material, providing a patterned photoresist on top of the layer of hard mask material, and then etching the layer of hard mask material to provide the hard mask pattern for etching the stack 120. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

Semiconductor layer 110 is further etched to form shallow trenches therein. Shallow trench isolation (STI) is formed in the etched trenches. In an embodiment, a dielectric liner 126 can be formed by depositing a conformal dielectric material, which can include, e.g., a SiN, or SiON, in the trenches. Then, the STI 128 is formed over the dielectric liner 126 using another dielectric material that is selectively etchable relative to the dielectric liner 126. For example, STI 128 can include, e.g., SiO₂, SiOₓN_{y}, SiCO or other suitable compounds. The dielectric liner 126 and the STI 128 can be deposited using chemical vapor deposition (CVD), although other deposition methods can be employed. The dielectric liner 126 and the STI 128 can then be etched, e.g., by RIE, to a level of the semiconductor layer 110.

A dummy gate material for dummy gates 132 is deposited and patterned using a patterned hard mask 130 and spacers 134, which are themselves patterned using, e.g., photolithographic patterning. The dummy gate material can include a polysilicon, amorphous Si or other selectively removeable material. The hard mask 130 is deposited over the material for the dummy gates 132, patterned and then used to etch the dummy gate material to form the dummy gates 132. Then, a deposition process and a spacer etch are employed to form spacers 134.

The hard mask 130 and spacers 134 can be employed as an etch mask to recess the nanosheet (e.g., stacks 120) to expose BDI 138. Regions of the nanosheet below the hard mask 130 and spacers 134 are patterned (e.g., in section X) for further processing while the nanosheet is completely removed in other regions (e.g., from section Y).

Inner spacers 140 are formed and include a dielectric material. In one embodiment, the inner spacers 140 are formed using exposed portions of the semiconductor layer 112, which can undergo a Ge condensation process to form a dielectric oxide (SiO₂) at the exposed portions by a thermal oxidation process. The oxidation process converts SiGe to the dielectric material and condenses out Ge. In other embodiments, portions of the semiconductor layer 112 can be laterally recessed and filled with dielectric material to form the inner spacers 140.

The hard mask 130 can be replaced by recessing the hard mask 130 and forming self-aligned caps (SAC) in place of the hard mask 130. Whether hard mask 130 is employed or SACs, the material should include a same or similar material as the spacers 134 to enable self-aligned patterning in later steps.

An epitaxial growth process is performed to form electrodes 148. Electrodes 148 are employed to form source and drain regions for transistors of the nanosheet FET device under construction. Electrodes can include Si or SiGe and include faceted surfaces when epitaxial growth is not confined. The electrodes 148 are epitaxially grown using material of the channel (semiconductor layer 114) as a starting structure. The electrodes 148 can be designated as P-type or N-type devices. For N-type devices, electrodes 148 can include Si. For P-type devices, the electrodes 148 can include SiGe. The electrodes 148 can be appropriately doped during their formation by epitaxial growth. For example, the electrodes 148 can be doped by introducing p dopants (e.g., B, Ga, etc.) during epitaxial formation. Similarly, the electrodes 148 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during the processing of the other.

A dielectric layer 150, such as, e.g., an interlevel dielectric layer (ILD) is formed on the wafer 100. The dielectric layer 150 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The dielectric layer 150 can be deposited using CVD, although other deposition methods can be employed.

After formation of the dielectric layer 150, a planarization process can be performed to planarize a top surface of the wafer 100. In one embodiment, the planarization process can include a chemical mechanical polish (CMP).

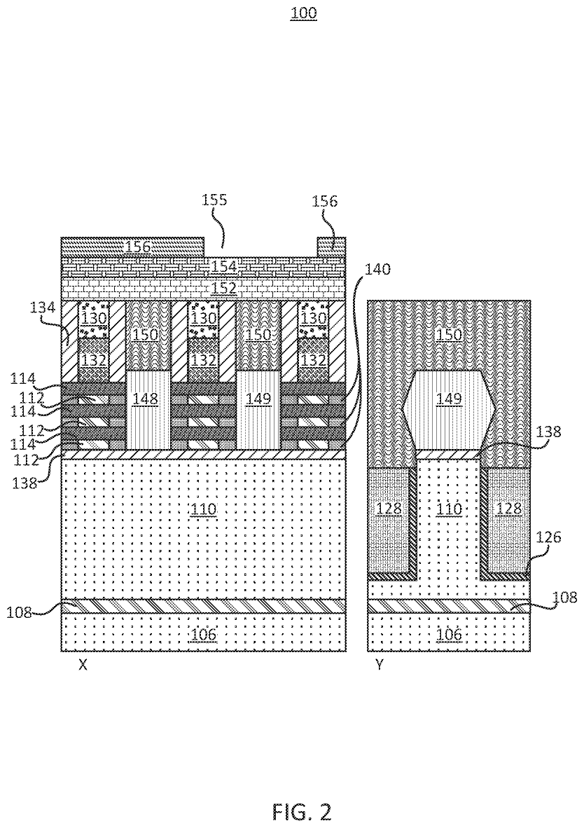

Referring to FIG. 2, a patternable material is deposited or spun onto a surface of the wafer 100. In one embodiment, a first layer 152 and a second layer 154 are deposited to form a hard mask. An organic planarization layer (OPL) 156 is formed over the second layer 154. In some embodiments, an anti-reflective coating (ARC) layer (not shown) may be formed on the OPL 156 followed by a layer of photoresist (not shown) formed on the ARC layer. The layer of photoresist can be imaged with an image pattern and developed to form an etch mask. The OPL 156 can be etched in accordance with the etch mask to open up openings 155 in the OPL 156 corresponding with a selected electrode 149 for each FET of the electrodes 148. The opening 155 has a large window since hard mask 130 (or SACs) and the spacers 134 provide an etch stop for a selective etch process that will remove the dielectric layer 150 from therebetween to expose the selected electrode 149 in later steps. The second layer 154 can include a mask material suitable for removing the dielectric layer 150, e.g., SiN, although other materials can be employed. The first layer 152 can include a mask material suitable for etching the selected electrode 149, e.g., SiN, although other materials can be employed.

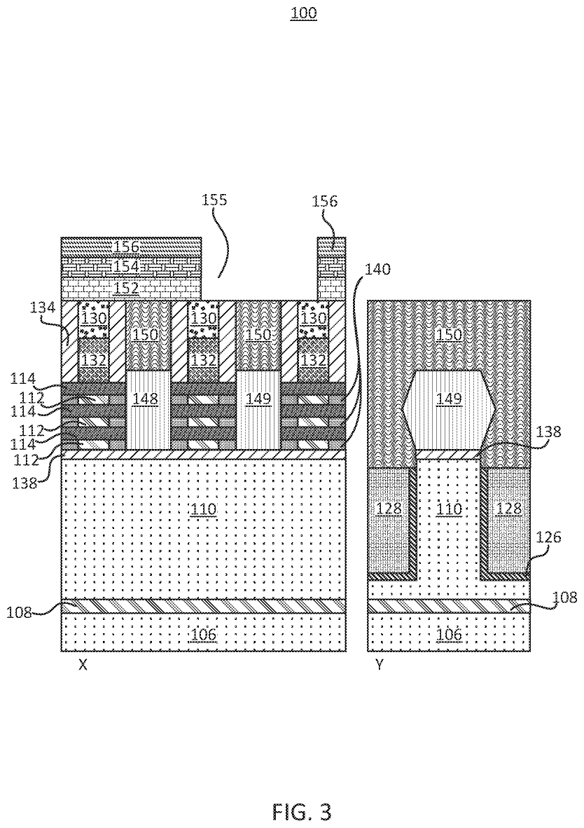

Referring to FIG. 3, an anisotropic etch, e.g., a reactive ion etch (RIE) etch or ion beam etch (IBE) is performed to etch the second layer 154 and the first layer 152 of the hard mask. The etch, such as a plasma dry etch, is self-aligned since a large window is available as a result the materials of the hard mask 130 and the spacers 134. The dielectric layer 150 is exposed over the selected electrode 149.

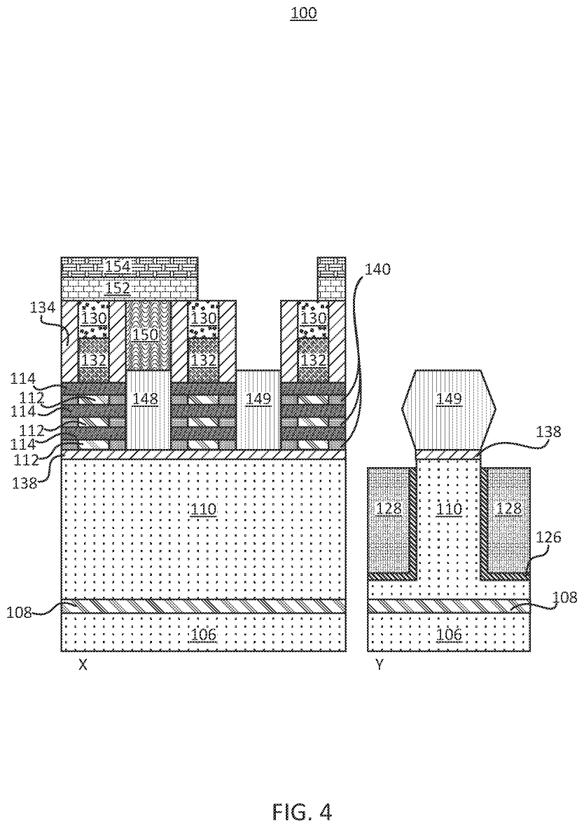

Referring to FIG. 4, the dielectric layer 150 is etched using, e.g., RIE to expose the selected electrode 149. The etch can be timed or selective to the material of the STI 128. The OPL 156 and the second layer 154 employed for a hard mask can be consumed in this etch process.

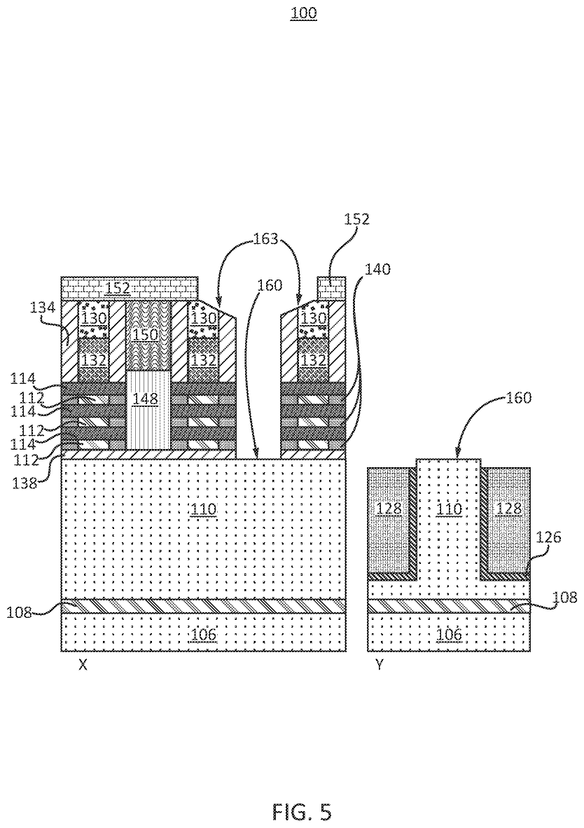

Referring to FIG. 5, the selected electrode 149 is etched and removed along with the BDI 138 in an area exposed to etching. The etch process can include, e.g., RIE. The etch process exposes a surface 160 of the semiconductor layer 110. As a result of sustained etching, portions 163 of the hard mask 130 and spacers 134 are eroded.

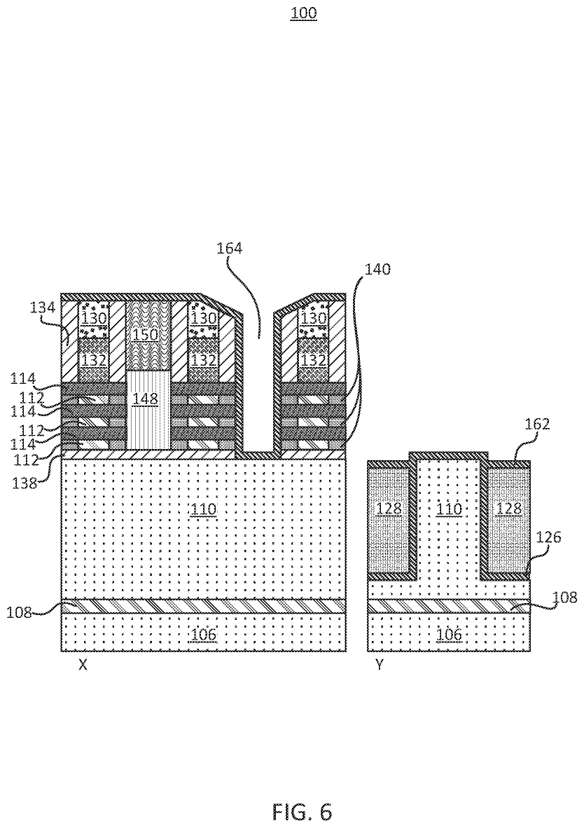

Referring to FIG. 6, a protective liner 162 is conformally deposited over the wafer 100 and covers surface 160 of semiconductor layer 110. The protective liner 162 covers the sidewalls of the opening 164 to protect channels formed by semiconductor layers 114.

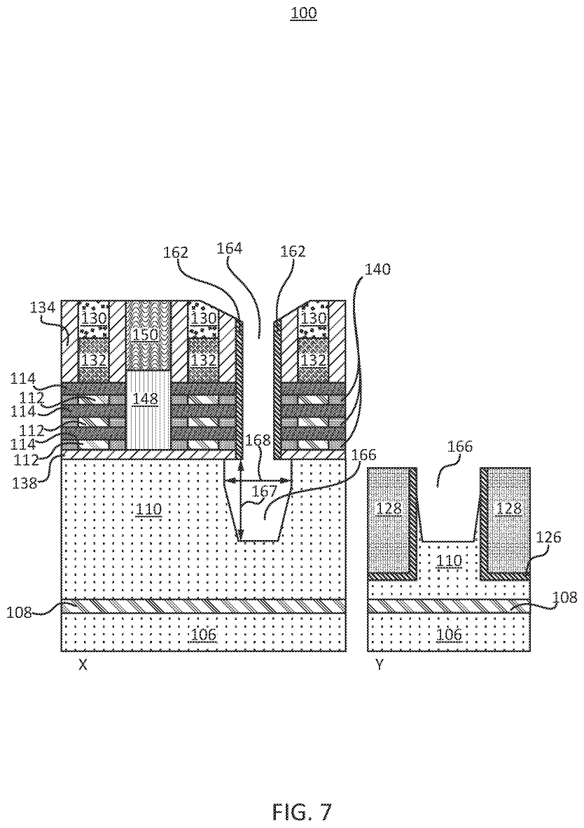

Referring to FIG. 7, a trench etch is performed to remove a portion of the semiconductor layer 110. The trench etch can include a RIE to open up a depth 167 of a trench 166 through opening 164. A wet etch can be performed to extend a width 168 of the trench 166 laterally. The wet etch can include, e.g., nitric acid and/or hydrofluoric acid. The protective liner 162 on horizontally disposed surfaces is consumed by the etching processes but remains on sidewalls (e.g., vertical surfaces) to provide protection for the channels (e.g., semiconductor layers 114).

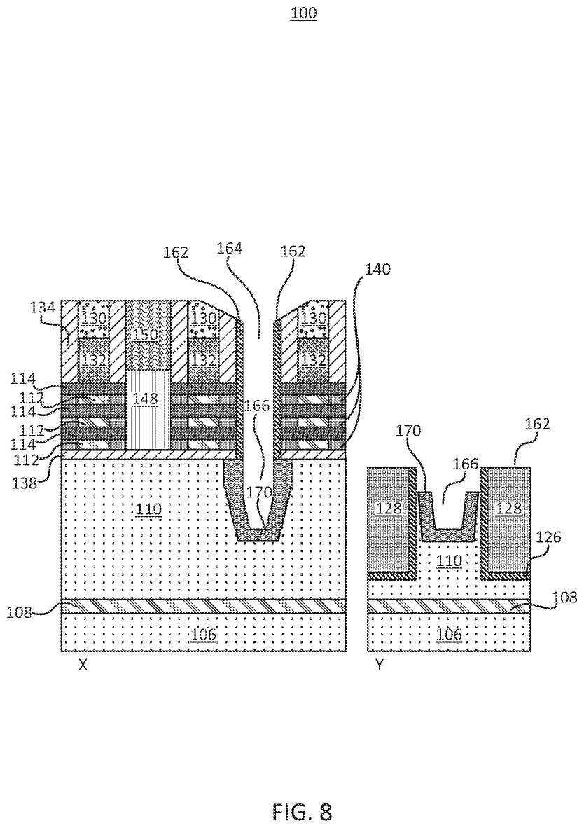

Referring to FIG. 8, a boundary surface 170 is formed within the semiconductor layer 110 within the trench 166. The boundary surface 170 is provided to create a difference in chemical properties of the material of the semiconductor layer 110. In this way, a boundary is created which can permit the removal of the material of the semiconductor layer 110 without damaging an extension portion that will be formed in later steps. In an embodiment, an epitaxial growth process can be performed. Introduction of Ge by a plasma generation process can be employed to grow a thin layer of SiGe as the boundary surface 170.

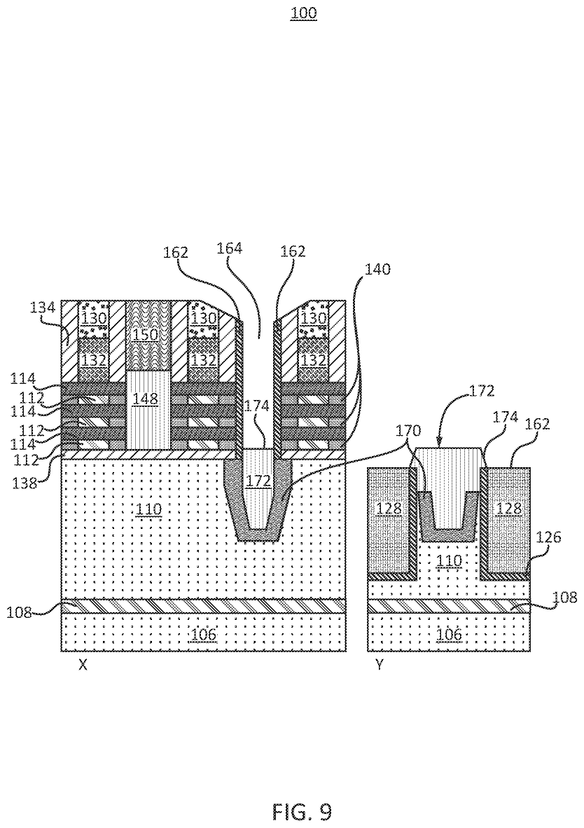

Referring to FIG. 9, an epitaxial growth process is employed to grow an extension portion 172 within the trench 166 (FIG. 8). The extension portion 172 is grown on the boundary surface 170 to initiate crystal growth and fills a remaining portion of the trench 166. In an embodiment, overburden 174 is provided which can provide a platform or pedestal for the formation of an active electrode to be formed in later steps. The overburden 174 can further provide a level that clears a level of the BDI 138 within the opening 164 but remains below adjacent semiconductor layers 114. The epitaxial growth process can be employed to grow Si, and in particular, a phosphorous-doped Si (Si:P), although other materials and dopants are contemplated.

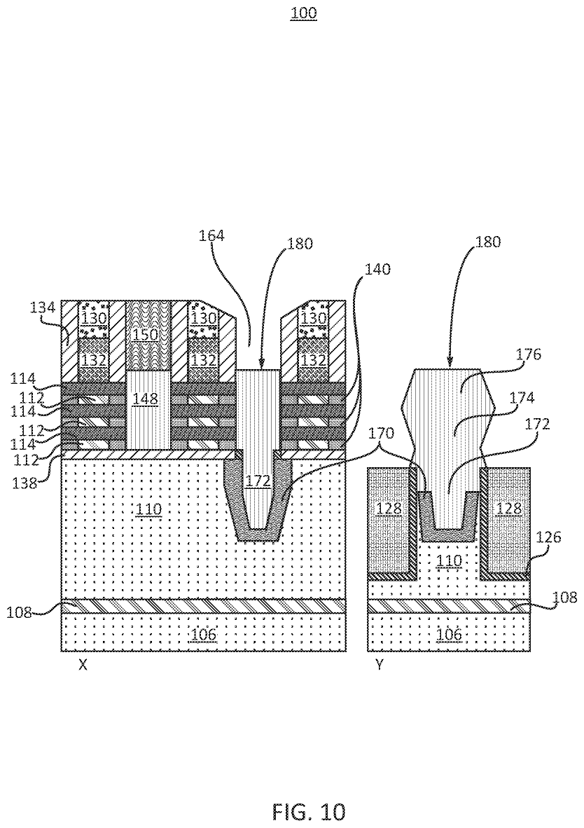

Referring to FIG. 10, the protective liner 162 is removed from the sidewalls of the opening 164 by a wet or plasma etch. The overburden 174 protects the BDI 138 and the dielectric liner 126 from etching. After the etch, the semiconductor layers 114 are exposed and provide a location for initiating crystal growth for an epitaxial growth process. The epitaxial growth process is employed to grow an epitaxial (epi) region 176 on the overburden 174 (if present). The epi region 176 is integrally formed with the extension portion 172 to form an asymmetric electrode 180. The asymmetric electrode 180 includes different dimensions for the extension portion 172, overburden 174 and the epi region 176. In addition, the asymmetric electrode 180 has a different size and shape than the electrode 148 of the same FET device.

The epitaxial growth process for the asymmetric electrode 180 can include Si, and in particular, a phosphorous-doped Si (Si:P), although other materials and dopants are contemplated. The asymmetric electrode 180 includes a faceted epi region 176, which can be formed on a platform provided by the overburden 174. The extension portion 172, which extends below a surface of the semiconductor layer 110 (e.g., within a depth of the STI 128) includes a faceted, stepped and otherwise complex curvature structure that has increased surface area for interfacing with a later-formed contact. In some embodiments, the epi region 176 includes a width that is greater than a width of the extension portion 172.

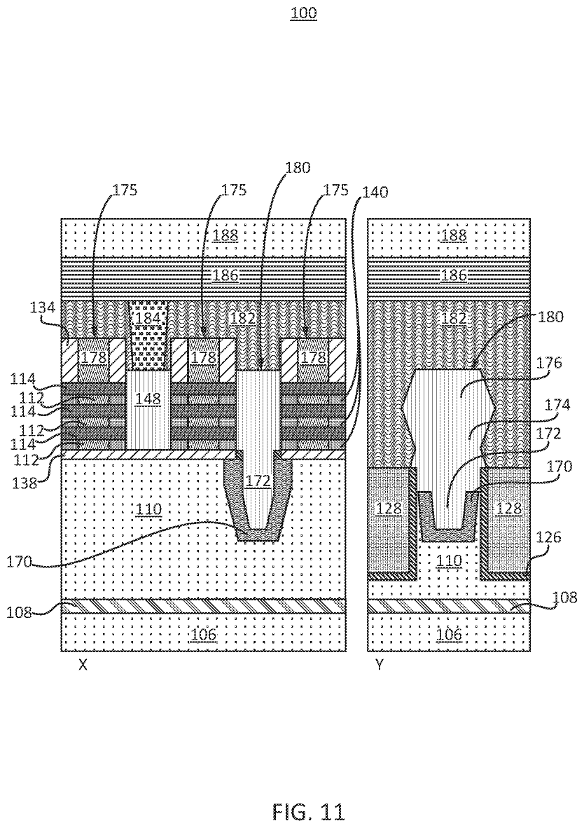

Referring to FIG. 11, dummy gates 132 and semiconductor layers 112 are removed by etching. This can include separate etch processes. The regions of the dummy gates 132 and the semiconductor layers 112 have a high dielectric constant (high-K) gate dielectric formed over semiconductor layer 114 followed by a gate metal fill to form gate electrodes 178. This process is known as a High-K Metal Gate (HKMG) process to form gate structures 175 for selectively activating FETs.

A dielectric layer 182 is deposited over the wafer 100. The same process used for the formation of dielectric layer 150 can be employed for dielectric layer 182, although dielectric layer 182 may include a different composition. The dielectric layer 182 is planarized, e.g., by CMP, which also removes the hard mask 130 and portions of the spacers 134.

Middle of the line (MOL) contacts 184 are formed to make connections with the electrodes 148 from a frontside of the wafer 100. Trenches or holes are formed in the dielectric layer 182, which forms a top interlevel dielectric layer. The trenches or holes expose the underlying active materials for the electrodes 148. In some embodiments, a silicide liner (not shown), such as Ti, Ni, NiPt is deposited first, then a diffusion barrier (not shown) can be formed in the trenches prior to a conductive fill. The diffusion barrier can include, e.g., TiN, TaN, or similar materials.

A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form contacts 184.

Processing continues with the formation of back end of the line (BEOL) layer 186, which can include metal structures and dielectric layers to complete a frontside or topside of the FET device and provide electrical access to the devices formed. A carrier wafer 188 can be bonded to the BEOL layer 186. The carrier wafer 188 provides support and transportability to the wafer 100 for further processing which includes flipping the wafer 100 and removing portions of a bottom side of the FET device.

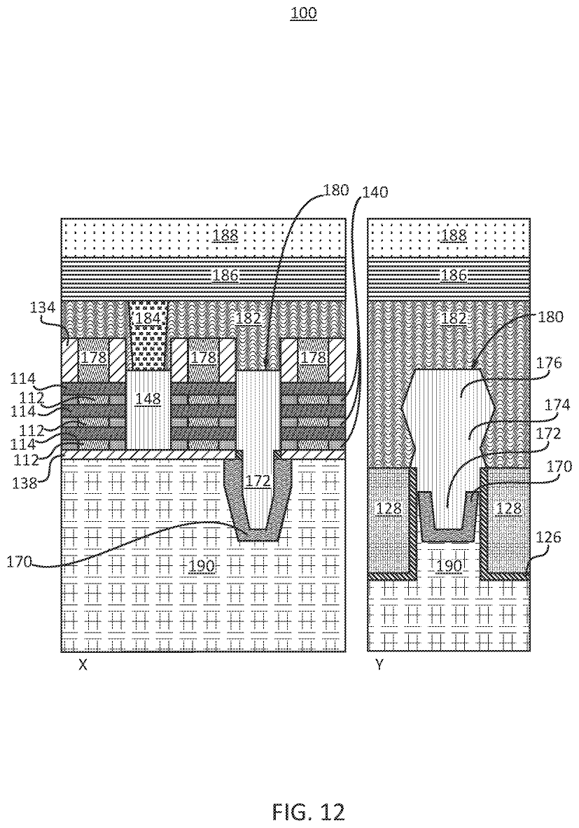

Referring to FIG. 12, to continue processing, the wafer 100 can be flipped to process features on the bottom side of the FET device. However, for clarity and consistency, the FET device will be shown in the FIGS. in a same orientation as previously described with continued and consistent reference to bottom/top. The substrate 106 is removed from the bottom side of the wafer 100. The substrate 106 can be removed by an etch process that stops on the etch stop layer 108. The etch stop layer 108 is then removed by an etch process. In an alternate embodiment, a CMP process can be employed to remove the substrate 106 and the etch stop layer 108. With the removal of the etch stop layer 108, the semiconductor layer 110 is exposed. The semiconductor layer 110 is removed by an etch process that selectively removes the material of the semiconductor layer 110 relative to the dielectric liner 126, the boundary surface 170 and BDI 138.

A dielectric layer 190 is formed over the dielectric liner 126, the boundary surface 170 and BDI 138. The dielectric layer 190 includes a material that is selectively removeable relative to the dielectric liner 126, the boundary surface 170 and BDI 138. The same process used for the formation of dielectric layer 150 can be employed for dielectric layer 190, although dielectric layer 190 may include a different composition. The dielectric layer 190 is planarized, e.g., by CMP.

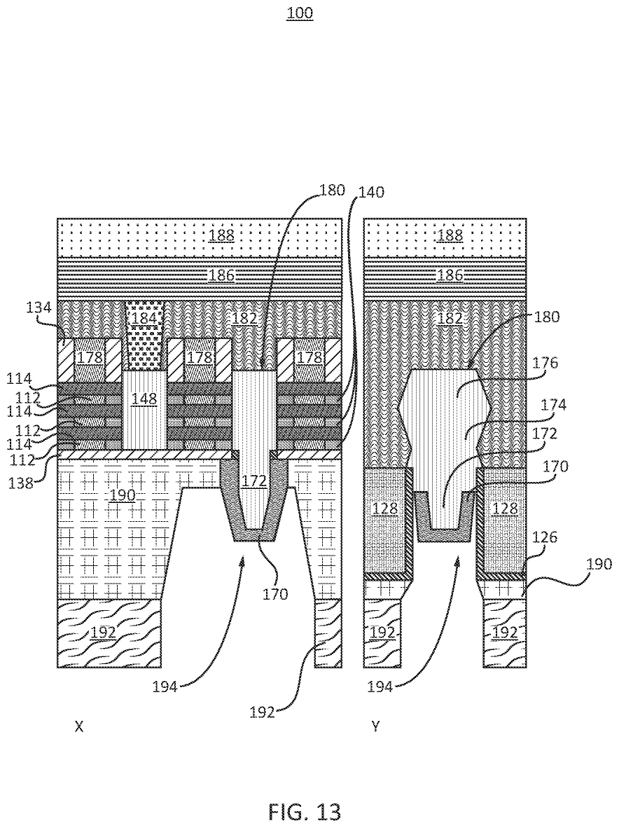

Referring to FIG. 13, backside contacts are formed to make connections with the asymmetric electrodes 180. Trenches or holes can be patterned using photolithographic patterning techniques to create an etch mask 192 to etch opening 194 with an anisotropic etch., e.g., RIE. The opening 194 is formed by removing material of the dielectric layer 190 selectively to the material of the boundary surface 170 and the dielectric liner 126 to expose the underlying boundary surface 170, which surrounds the extension portion 172.

In an embodiment, one opening 194 is opened up per FET on a backside of the FET device such that only one electrode (source or drain) is contacted at the backside of the FET and only one electrode (drain or source) is contacted by contact 184 at the frontside of the FET. In this way, contact density is reduced on the frontside and the backside of the FET. This reduces or eliminates the possibility of shorts or opens that would otherwise be experienced under shrinking device sizes.

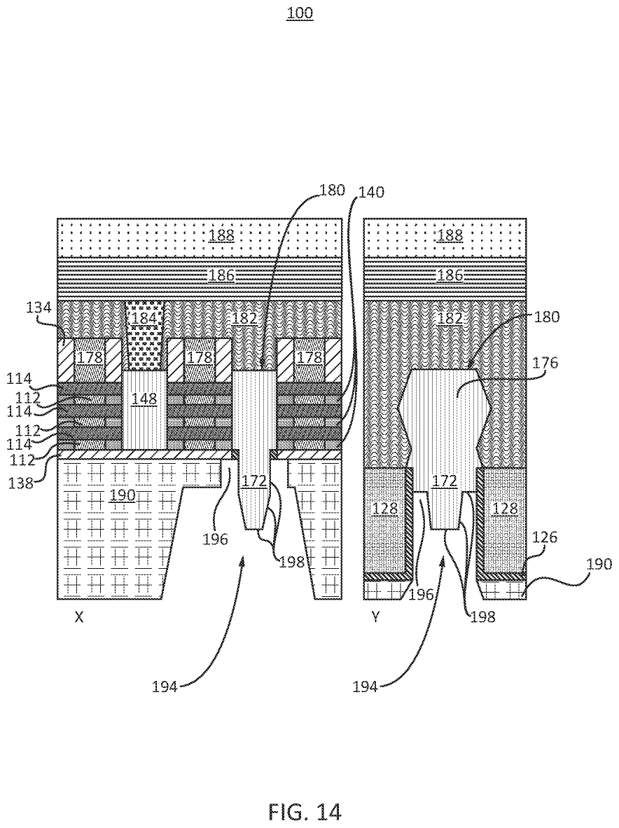

Referring to FIG. 14, further selective etching removes the boundary surface 170 from the extension portion 172 to open up regions 196. The etch process can include a dry etch or wet etch that selectively removes the boundary surface 170 relative to the extension portion 172, dielectric liner 126 and BDI 138. The corresponding extension portion 172 is now exposed. Multiple faceted surfaces 198 are exposed on the extension portion 172 which increases the exposed surface area and therefore the contact area for contacts to be formed. Multiple faceted surfaces 198 include horizontally and vertically disposed facets.

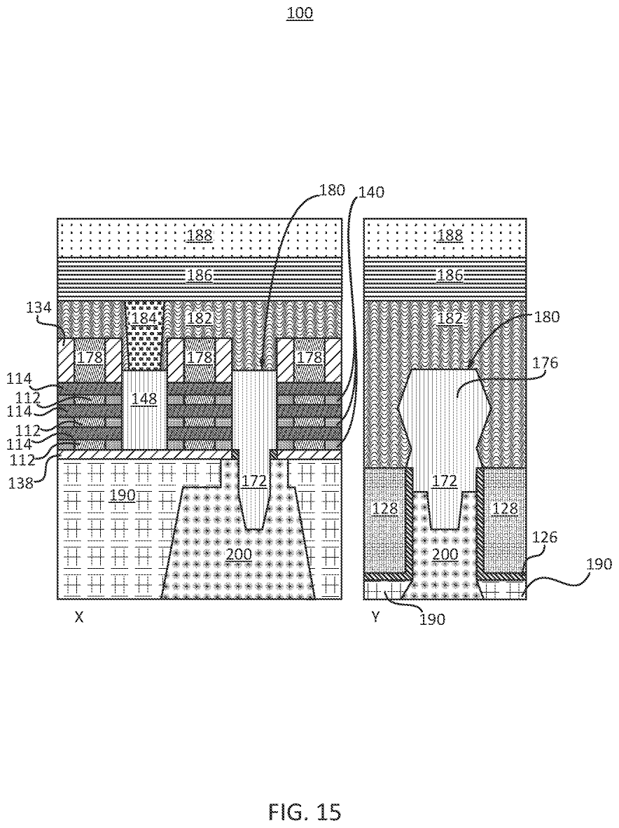

Referring to FIG. 15, a silicide liner (not shown), such as Ti, Ni, NiPt can be deposited first, then a diffusion barrier (not shown) can be formed in the opening 194 (FIG. 14) prior to a conductive fill. The diffusion barrier can include, e.g., TiN, TaN, or similar materials. A conductive fill is performed to fill the opening 194. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form backside contact 200.

The backside contact 200 interfaces with one or more facets of the multiple faceted surfaces 198 (FIG. 14) of the extension portion 172. All of the facets of the multiple faceted surfaces 198 provide a three-dimensional interface which significantly increases contact area between the asymmetric electrode 180 and the backside contact 200. The backside contact 200 includes a width (section X) that extends below adjacent gate structures 175 on the backside of the wafer 100.

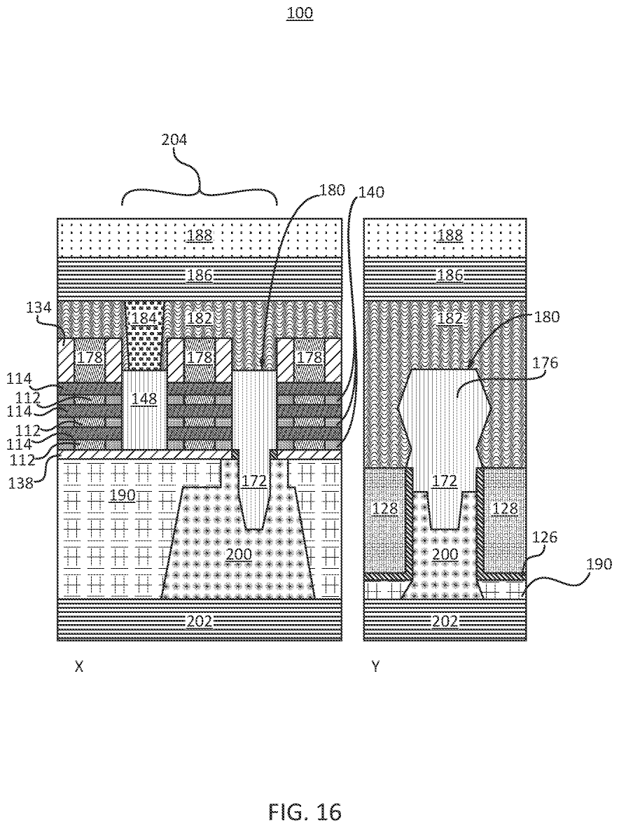

Referring to FIG. 16, processing continues with the formation of a backside interconnect layer 202, which can include metal structures and dielectric layers to complete the bottom side of the FET device and provide electrical access to the devices formed. The backside interconnect layer 202 is formed on the dielectric layer 190 and the backside contact 200. The backside contact 200 is a wraparound contact that addresses contact resistance issues. The structure of the wraparound contact increases surface area between the backside contact 200 and the extension portion 172.

A FET device 204 includes an electrode 148 with a topside contact 184 and an electrode (asymmetric electrode 180) with a backside wrap around contact 200. By dividing the contacts between a frontside and backside, the risk of shorts and opens is greatly diminished. Source and drain regions are interchangeable for the electrode 148 and the asymmetric electrode 180.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising.” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a shallow trench isolation region having a depth;
an asymmetric electrode having:
an epitaxial region outside the depth of the shallow trench isolation region; and
an epitaxial extension portion within the depth of the shallow trench isolation region and connected to the epitaxial region; and
a backside contact in contact with the epitaxial extension portion to provide a wraparound contact to reduce contact resistance.

2. The semiconductor device as recited in claim 1, wherein the asymmetric electrode includes a source region or a drain region of a field effect transistor and another of the source region or the drain region is contacted by a contact from a topside of the semiconductor device.

3. The semiconductor device as recited in claim 1, wherein the asymmetric electrode includes an overburden disposed between the epitaxial region and the epitaxial extension portion.

4. The semiconductor device as recited in claim 1, wherein the backside contact is disposed within the depth of the shallow trench isolation region.

5. The semiconductor device as recited in claim 1, wherein the epitaxial region includes a width that is greater than a width of the epitaxial extension portion.

6. The semiconductor device as recited in claim 1, wherein the epitaxial extension portion includes a faceted surface that includes horizontally and vertically disposed facets and the backside contact interfaces with the horizontally and the vertically disposed facets.

7. The semiconductor device as recited in claim 1, wherein the epitaxial region is on a frontside of the semiconductor device and the epitaxial extension portion is on a backside of the semiconductor device.

8. The semiconductor device as recited in claim 1, wherein the backside contact includes a width that spans between adjacent gate structures on the backside of the semiconductor device.

9. A semiconductor device, comprising:
a field effect transistor having a first electrode and a second electrode;
the first electrode including an asymmetric electrode having:
an epitaxial region on a frontside of the semiconductor device; and
an epitaxial extension portion on a backside of the semiconductor device and connected to the epitaxial region, the epitaxial extension portion including a faceted surface;
a backside contact in contact with the faceted surface from the backside to provide a wraparound contact to reduce contact resistance; and
a frontside contact in contact with the second electrode from the frontside.

10. The semiconductor device as recited in claim 9, wherein the first electrode is a source region or a drain region of the field effect transistor and the second electrode is another of the source region or the drain region.

11. The semiconductor device as recited in claim 9, wherein the first electrode includes an overburden disposed between the epitaxial region and the epitaxial extension portion.

12. The semiconductor device as recited in claim 9, wherein the backside contact is disposed within a depth of a shallow trench isolation region.

13. The semiconductor device as recited in claim 9, wherein the epitaxial region includes a width that is greater than a width of the epitaxial extension portion.

14. The semiconductor device as recited in claim 9, wherein the faceted surface includes horizontally and vertically disposed facets and the backside contact interfaces with the horizontally and the vertically disposed facets.

15. The semiconductor device as recited in claim 9, wherein the backside contact includes a width that spans between adjacent gate structures on the backside of the semiconductor device.

16. A semiconductor device, comprising:
a field effect transistor having a first electrode and a second electrode; the first electrode and the second electrode each including an epitaxial region on a frontside of the semiconductor device;
the first electrode having an epitaxial extension portion on a backside of the semiconductor device and connected to the epitaxial region of the first electrode, the epitaxial extension portion including a faceted surface that extends toward the backside of the semiconductor device, the faceted surface including horizontally and vertically disposed facets;
a backside contact in contact with the faceted surface from the backside to provide a wraparound contact that interfaces with the horizontally and the vertically disposed facets to reduce contact resistance; and
a frontside contact in contact with the epitaxial region of the second electrode from the frontside.

17. The semiconductor device as recited in claim 16, wherein the first electrode is a source region or a drain region of the field effect transistor and the second electrode is another of the source region or the drain region.

18. The semiconductor device as recited in claim 16, wherein the first electrode includes an overburden disposed between the epitaxial region and the epitaxial extension portion.

19. The semiconductor device as recited in claim 16, wherein the backside contact is disposed within a depth of a shallow trench isolation region.

20. The semiconductor device as recited in claim 16, wherein the backside contact includes a width that spans between adjacent gate structures on the backside of the semiconductor device.
